(19) United States
(12) Patent Application Publication
(10) Pub. No.: US 2026/0198390 A1
(43) Pub. Date: Jul. 9, 2026

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Chen-Shien CHEN, Hsinchu County (TW); Yao-Chun Chuang, Hsinchu City (TW); Chen-Nan Chiu, Hsinchu City (TW); Jui Shen Chang, Taichung City (TW); Yu-Sheng Lin, Hsinchu County (TW); Hsu-Hsien Chen, Hsinchu City (TW)

(73) Assignee: Taiwan Semiconductor Manufacturing Company, Ltd., Hsinchu (TW)

(21) Appl. No.: 19/015,555

(22) Filed: Jan. 9, 2025

(51) Int. Cl. H01L 23/498; H01L 21/48

(52) U.S. Cl. CPC H10W 90/701; H10W 70/093

(57) ABSTRACT

A package structure includes a package substrate, first and second terminal structures disposed on a first side of the package structure. Each of the first terminal structures includes a first conductive core, a first conductive coating wrapping around the first conductive core, and a first conductive shell wrapping around the first conductive coating. Each of the second terminal structures includes a second conductive core, a second conductive coating wrapping around the second conductive core, and a second conductive shell wrapping around the second conductive coating. The second conductive coating includes a material different from a material of the first conductive coating.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. These smaller electronic components also require smaller packages that occupy less area than previous packages. Thus, new packaging technologies have begun to be developed. For example, some packages rely on bumps of solder to provide an electrical connection, and the different layers making up the interconnection in the packages have different coefficients of thermal expansion (CTEs). As a result, a relatively large stress derived from this difference is exhibited on the joint area, which causes the risk of delamination and/or cold joint. These relatively new types of packaging technologies for semiconductor devices face manufacturing challenges.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4A, 5A, and 6 are schematic cross-sectional views of various stages of manufacturing a package structure, in accordance with some embodiments.

FIG. 4B is a schematic plan view of a mask structure, in accordance with some embodiments.

FIG. 5B is a schematic plan view of a structure shown in FIG. 5A, in accordance with some embodiments.

FIG. 7 is a schematic cross-sectional view of another implementation of a package structure, in accordance with some embodiments.

FIGS. 8-9 are schematic cross-sectional views of various stages of manufacturing a package structure, in accordance with some embodiments.

FIGS. 10A-10D are schematic enlarged cross-sectional views of a first terminal structure, in accordance with some embodiments.

FIGS. 11A-11C are schematic enlarged cross-sectional views of a second terminal structure, in accordance with some embodiments.

FIGS. 12A and 12B are schematic cross-sectional views of another implementations of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

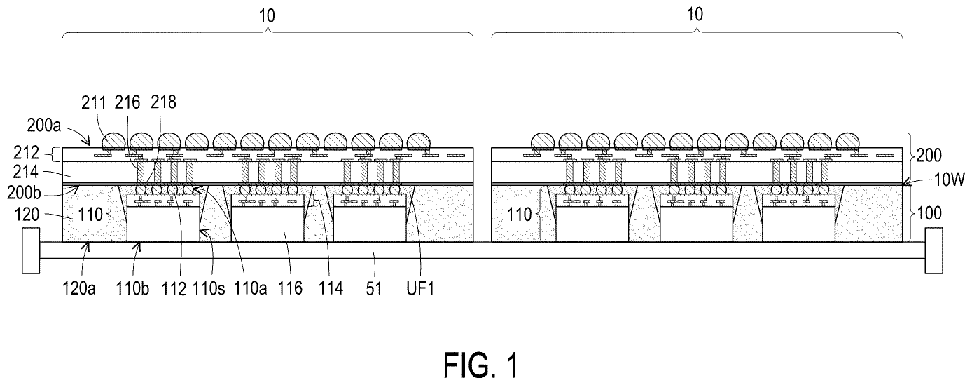

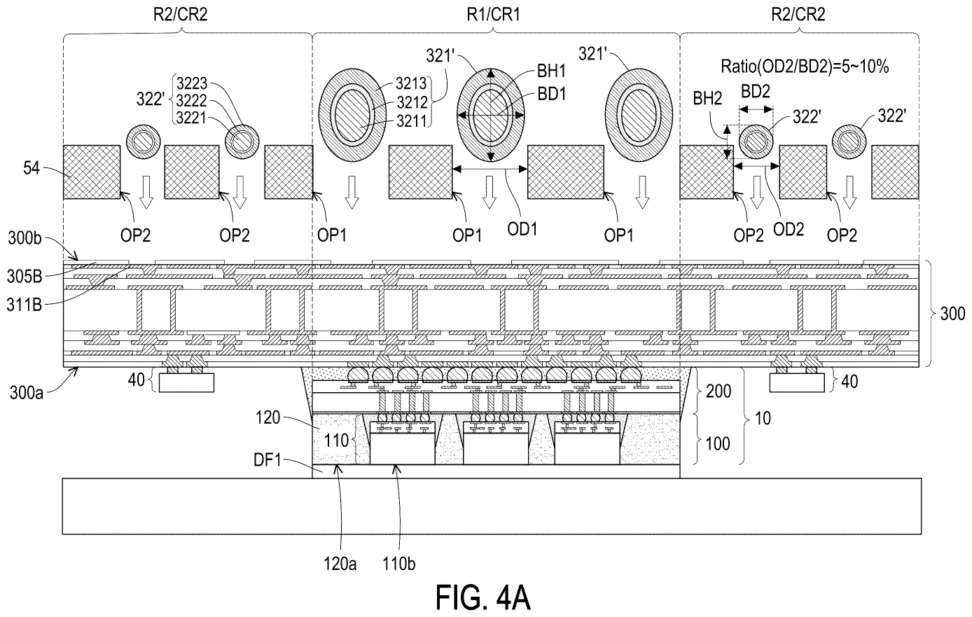

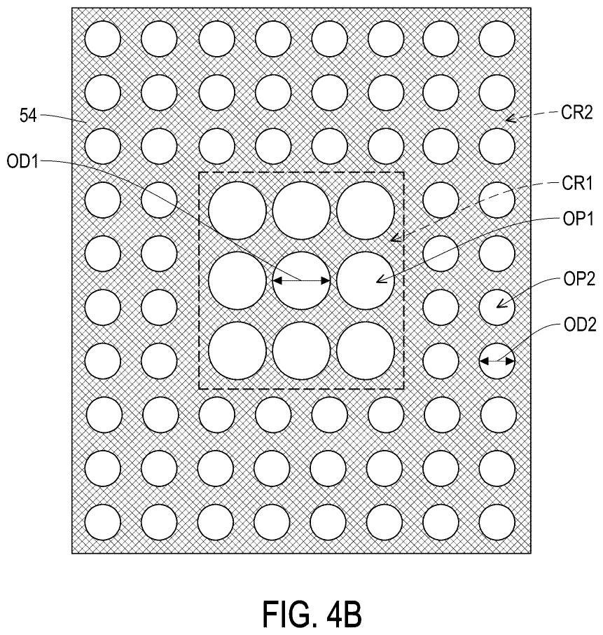

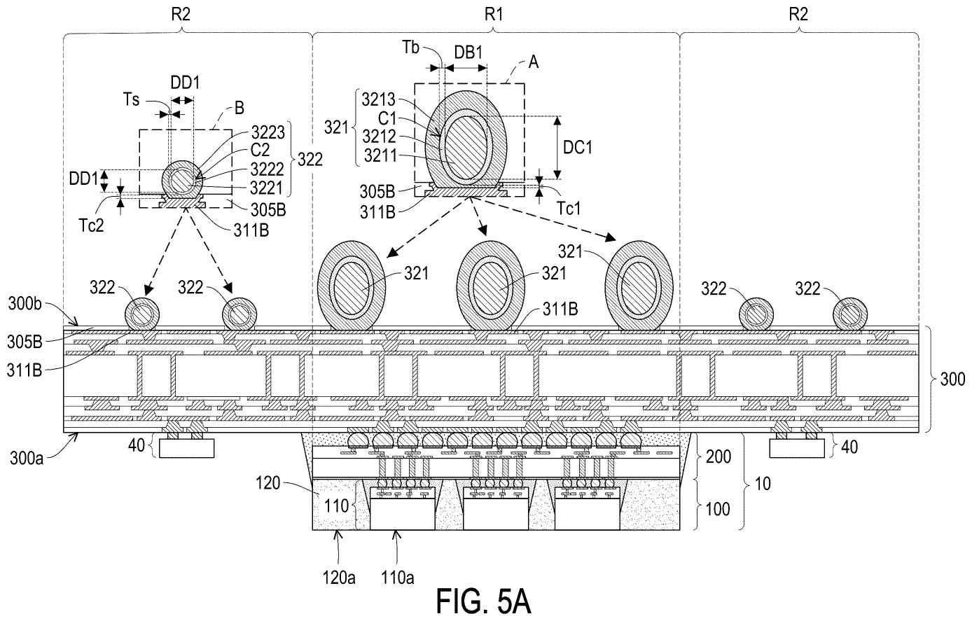

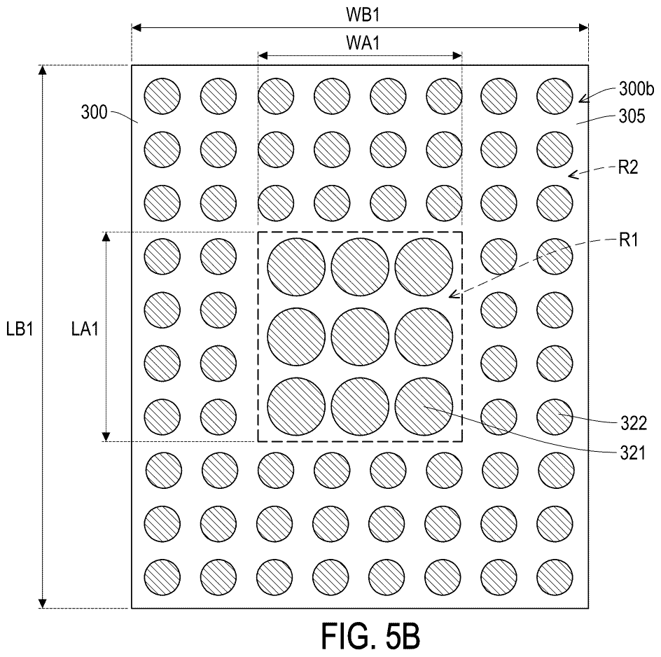

FIGS. 1-4A, 5A, and 6 are schematic cross-sectional views of various stages of manufacturing a package structure, FIG. 4B is a schematic plan view of a mask structure, and FIG. 5B is a schematic plan view of a structure shown in FIG. 5A, in accordance with some embodiments.

Referring to FIG. 1, a first package component 100 and a second package component 200 electrically coupled to the first package component 100 may be provided. In some embodiments, the first package component 100 and the second package component 200 are collectively viewed as a device package 10. A plurality of device packages 10 may be disposed on a tape frame 51. In some embodiments, the tape frame 51 includes a carrier on which a temporary adhesive is coated. For example, the first package component 100 is attached to the tape frame 51, and the second package component 200 is disposed on the first package component 100. In some embodiments, the device packages 10 are provided in a wafer form and mounted on the tape frame 51, and then a dicing process is performed on the wafer to separate the device packages 10 from one another. In some embodiments, after the dicing process, the outer sidewall of the first package component 100 is substantially leveled (or coplanar) with the outer sidewall of the second package component 200, within process variations. The tape frame 51 may be referred to as a dicing tape frame. In alternative embodiments, the tape frame 51 is replaced with another suitable type of temporary carrier.

With continued reference to FIG. 1, the respective first package component 100 may include at least one semiconductor die 110 encapsulated by an insulating encapsulation 120. The respective semiconductor die 110 may include a first side 110a, a second side 110b opposite to the first side 110a, and a sidewall 110s connected to the first side 110a and the second side 110b. In some embodiments, the semiconductor die 110 includes die connectors 112 (e.g., micro-bumps, metal pillars with or without caps, controlled collapse chip connection (C4) bumps, or the like) distributed at the first side 110a for electrically connecting the second package component 200. The respective semiconductor die 110 may (or may not) include an interconnecting layer 114 for connecting the active/passive devices (not shown) formed on/in the semiconductor substrate 116 to the die connectors 112. The semiconductor substrate 116 may refer to a semiconductor material(s) including, but not limited to, bulk silicon, a semiconductor wafer, a silicon germanium substrate, silicon-on-insulator (SOI) substrate, or the like. Other semiconductor materials including group III, group IV, and group V elements may be used. In some embodiments, the interconnecting layer 114 includes a plurality of dielectric sublayers, metal lines formed in the dielectric sublayers, and conductive vias formed between overlying and underlying metal lines. It is noted that the configuration and the number of the semiconductor dies 110 shown herein is merely for illustrative purposes, and any other configuration and number of the semiconductor dies 110 may be employed depending on product requirements.

With continued reference to FIG. 1, the respective semiconductor die 110 may have a single function (e.g., a logic die, a processor die (e.g., a central processing unit (CPU) die, a graphics processing unit (GPU) die, an application-specific integrated circuit (ASIC) die, etc.), a memory die (e.g., a dynamic random-access memory (DRAM) die, a static random-access memory (SRAM) die, a stacked memory module, a high-bandwidth memory (HBM) die, etc.), a RF die, a mixed signal die, a I/O die, combinations thereof, and/or the like). For example, the semiconductor dies 110 are formed in a device wafer (not shown), which includes different die regions that are singulated to form a plurality of semiconductor dies 110. After the singulation, the semiconductor dies 110 are mounted on the predetermined locations of the second package component 200. In some embodiments, the semiconductor dies 110 may be of different sizes (e.g., footprint areas) and have different functions. Alternatively, the semiconductor dies 110 may be of the same/similar dimension(s). Other types of semiconductor dies 110 may be used depending on product requirements.

With continued reference to FIG. 1, the insulating encapsulation 120 may extend along at least the sidewalls 110s of the semiconductor dies 110 for protection. The insulating encapsulation 120 may be or may include molding compound, epoxy resin, molding underfill, and/or the like, and may be applied by compression molding, transfer molding, or the like. For example, the insulating encapsulation 120 is formed over the second package component 200, and the semiconductor dies 110 are buried or covered by the insulating encapsulation 120. In some embodiments, the insulating encapsulation 120 is thinned to expose the second sides 110b of the semiconductor dies 110. The thinning process may be performed by a chemical-mechanical polishing (CMP) process, a grinding process, an etching process, a combination thereof, and/or the like. In some embodiments, after the thinning process, the first surface 120a of the insulating encapsulation 120 and the second sides 110b of the semiconductor dies 110 are substantially leveled (or coplanar), within process variations.

With continued reference to FIG. 1, an underfill layer UF1 is optionally formed between the gap of the respective semiconductor die 110 and the second package component 200 to laterally cover the electrical connections of the die connectors 116 and the second package component 200. In some embodiments, a portion of the underfill layer UF1 climbs upward to at least partially cover the sidewalls 110s of the semiconductor dies 110. The insulating encapsulation 120 may be formed after the formation of the underfill layer UF1, so that the rest portions of the sidewalls 110s of the semiconductor dies 110 that are unmasked by the underfill layer UF1 may be covered by the insulating encapsulation 120. Alternatively, the underfill layer UF1 is omitted, and the gaps between the semiconductor dies 110 and the second package component 200 may be covered by the insulating encapsulation 120 (e.g., the molding underfill).

With continued reference to FIG. 1, the second package component 200 may (or may not) include active devices and/or passive devices. In some embodiments, the second package component 200 acts as an interposer. The semiconductor dies 110 may be electrically coupled to one another through the second package component 200. For example, the second package component 200 includes an interconnect structure 212 on a first side 200a of the second package component 200. The interconnect structure 212 may include a plurality of dielectric layers, conductive patterns embedded in the dielectric layers, and conductive vias interconnecting two vertically adjacent levels of the conductive patterns. In some embodiments, additional interconnect structure is formed at a second side 200b opposite to the first side 200a for electrically connecting the semiconductor dies 110. In some embodiments, the second package component 200 includes a plurality of conductive terminals 211 distributed at the first side 200a and connected to the interconnect structure 212. The conductive terminals 211 may be or may include C4 bumps, metal pillars, electroless nickel-electroless palladium-immersion gold technique (ENEPIG) formed bumps, solder balls, ball-grid-array (BGA) connectors, and/or the like.

With continued reference to FIG. 1, the interconnect structure 212 may be formed on a semiconductor substrate 214. The semiconductor substrate 214 may have a material similar to the material of the semiconductor substrate 116 or may be formed of other suitable material(s). For example, after the dicing process, the device packages 10 has edges formed by a coterminous sidewall 10W of the interconnect structure 212, the semiconductor substrate 214, and the insulating encapsulation 120. The second package component 200 may include a plurality of conductive through-vias 216 penetrating through the semiconductor substrate 214 to provide vertical and electrical connections between two opposing sides of the semiconductor substrate 214. For example, the conductive through-vias 216 are electrically connected to the conductive patterns of the interconnect structure 212 and extending toward the first package component 100 to be connected to the conductive patterns 218 (e.g., contact pads) at the second side 200b of the second package component 200. The die connectors 112 of the first package component 110 may be in physical and electrical contact with one side of the conductive patterns 218, and the conductive through-vias 216 are connected to the other side of the conductive patterns 218. The second package component 200 optionally includes a dielectric layer formed on the semiconductor substrate 214 to cover the conductive patterns 218 (e.g., contact pads) for protection, and the insulating encapsulation 120 (and the underfill layer UF1, if exist) may be formed on the dielectric layer.

In alternative embodiments, the second package component 200 is formed as a fan-out redistribution structure, where the semiconductor substrate 214 and the conductive through-vias 216 are omitted or may be replaced with other interconnecting layer(s). Under such implementation, the first package component and the second package component are collectively viewed as an integrated fan-out (InFO) package. It is noted that the second package component 200 illustrated herein is merely for illustrative purposes, and additional or fewer element(s) may be arranged in the second package component 200.

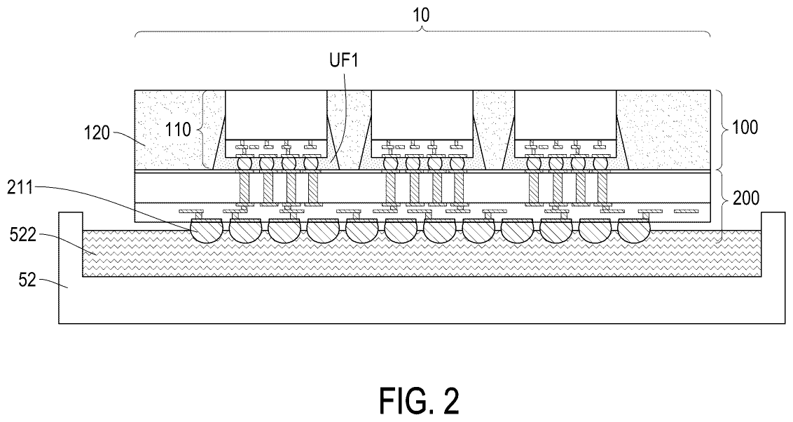

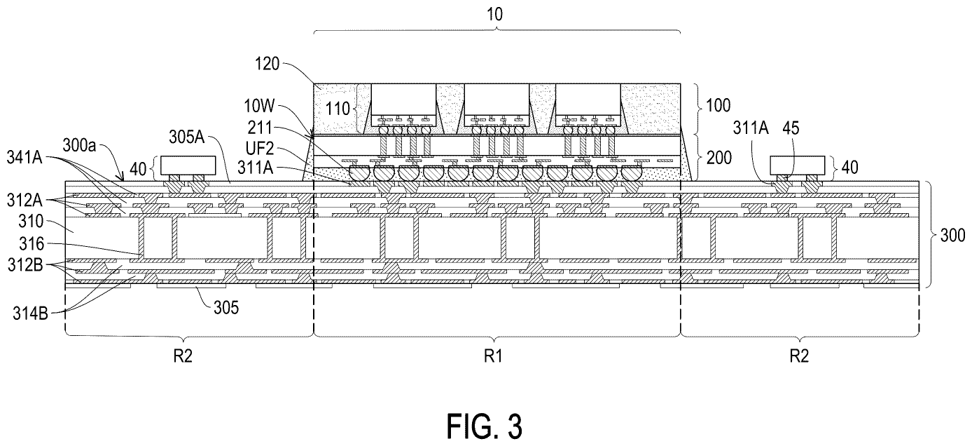

Referring to FIGS. 2-3 and with reference to FIG. 1, the respective device package 10 may be disposed on and connected to a first side 300a of a third package component 300, for example, by sequentially dipping the conductive terminals 211 into flux material 522, and then using a pick-and-place tool (not shown) to physically align the respective device package 10 with the corresponding region of the third package component 300. In some embodiments, the flux material 522 includes a liquid that is poured into a tray 52, and the partially device package 10 may be placed proximate the tray 52 and lowered towards the flux material 522 until the conductive terminals 211 are at least partially submerged in the flux material 522. A portion of the flux material 522 may adhere to the conductive terminals 211. Alternatively, the flux material 522 may be sprayed onto the conductive terminals 211. The flux material 522 may also be formed on the conductive terminals 211 using other suitable methods.

With continued reference to FIG. 3, the device package 10 may be disposed on the third package component 300, and a reflow process may be performed on the conductive terminals 211 to bond the conductive terminals 211 to the third package component 300. In some embodiments, the underfill layer UF2 is formed between the gap of the second package component 200 and the third package component 300 to surround the conductive terminals 211 for protection. In some embodiments, a sufficient amount of underfill material is dispensed, and a portion of the underfill layer UF2 climbs upward to at least partially cover the sidewalls 10W of the device package 10. Alternatively, the underfill layer UF2 is omitted.

With continued reference to FIG. 3, the first side 300a of the third package component 300 may be in physical and electrical contact with the conductive terminals 211 of the second package component 200, where the second package component 200 is interposed between the first package component 100 and the first side 300a of the third package component 300. In some embodiments, the third package component 300 includes contact pads 311A at the first side 300a for the conductive terminals 211 landing thereon. A mask layer 305A (e.g., a solder resist layer or the like) is optionally formed to partially cover the contact pads 311A to prevent bridging and protect the underlying trace layers. In some embodiments, the third package component 300 is a laminate package substrate, where the conductive patterns are embedded in laminated dielectric layers. In some embodiments, the third package component 300 is a built-up package substrate, which includes a core layer 310 (e.g., BT resin, FR-4, ceramic, glass, plastic, or other supporting materials), the trace layers (312A and 312B) respectively built on opposite sides of the core layer 310, dielectric layers (314A and 314B) respectively covering the trace layers (312A and 312B), and through-vias 316 penetrating through the core layer 312 to connect the trace layers (312A and 312B) at the opposite sides of the core layer 312. For example, the contact pads 311A are formed on the trace layers 312A, where each of the trace layers (312A and 312B) including conductive pads, conductive vias, and conductive lines, etc. In some embodiments, the package substrate is a multiple-layered circuit board (e.g., a printed circuit board (PCB)) or other types of package substrates depending on product requirements.

Still referring to FIG. 3, the device package 10 may be arranged in the first region R1 of the third package component 300. In some embodiments, one or more fourth package component(s) 40 is/are bonded to the first side 300a of the third package component 300 and arranged within the second region R2. For example, the first region R1 is surrounded by the second region R2. It is appreciated that due to the difference between different materials of the plurality of package components, warpage may occur. For example, differing coefficients of thermal expansion (CTEs) between elements of the device package 10 and elements of the third package component 300 may contribute to warpage. In some embodiments, the device package 10 in the first region R1 dominates warpage of the resulting package structure as compared to the fourth package component(s) 40 in the second region R2. The fourth package component(s) 40 may be or may include integrated passive devices (IPD), integrated voltage regulators (IVR), active components, and/or the like. In some embodiments, the respective fourth package component 40 is mounted on the third package component 300 through the device connectors 45 landing on the contact pads 311A of the third package component 300. Other types of the connection between the third and the fourth package components may be used. It is noted that FIG. 3 showing two of the fourth package components 40 is merely for illustrative purposes, and the number and the configuration of the fourth package components 40 construe no limitation in the disclosure.

Referring to FIGS. 4A-4B with reference to FIG. 3, the structure of FIG. 3 may be flipped upside-down and placed over a temporary carrier 53. A material of the temporary carrier 53 may include glass, metal, ceramic, silicon, plastic, combinations thereof, multi-layers thereof, or other suitable material(s) that may provide structural support for the overlying structure in subsequent processing. In some embodiments, attaching the device package 10 to the temporary carrier 53 includes bonding the first surface 120a of the insulating encapsulation 120 and the second sides 110b of the semiconductor dies 110 to the temporary carrier 53 through a temporary adhesive layer DF1. The temporary adhesive layer DF1 may be or may include a polymer layer, ultra-violet cured layer, and/or other suitable temporary adhesives. Alternatively, the temporary adhesive layer DF1 is omitted.

With continued reference to FIGS. 4A-4B and FIG. 3, a mask structure 54 may be placed over a second side 300b of the third package component 300 opposite to the first side 300a. In some embodiments, the mask structure 54 is a stencil and includes first openings OP1 and second openings OP2, where the sizes of the first openings OP1 and the second openings OP2 are different. For example, the respective first opening OP1 has a lateral dimension OD1 greater than a lateral dimension OD2 of the respective second opening OP2. In some embodiments, the first openings OP1 are arranged in an array within the central region CR1 of the mask structure 54, while the second openings OP2 are distributed within the peripheral region CR2 of the mask structure 54 surrounding the central region CR1, as shown in the plan view of FIG. 4B. As the mask structure 54 is placed over the third package component 300, the central region CR1 of the mask structure 54 having the first openings OP1 may overlap (or be directly over) the first region R1 of the third package component 300, while the peripheral region CR2 of the mask structure 54 having the second openings OP2 may overlap (or be directly over) the second region R2 of the third package component 300.

With continued reference to FIG. 4A, the first openings OP1 and the second openings OP2 of the mask structure 54 may be substantially aligned with the contact pads 311B, so that the first conductive balls 321′ and the second conductive balls 322′ may be accurately placed on portions of the contact pads 311B revealed by the mask layer 305B. After the mask structure 54 is placed over the second side 300b of the third package component 300, first conductive balls 321′ and second conductive balls 322′ may be respectively dropped in the first openings OP1 and the second openings OP2. In some embodiments, the first conductive balls 321′ pass through the first openings OP1 before the second conductive balls 322′ pass through the second openings OP2.

With continued reference to FIG. 4A, the size and the volume of the respective first conductive ball 321′ may be greater than those of the respective second conductive ball 322′. In some embodiments, the cross-sectional profiles of the respective first conductive ball 321′ and the respective second conductive ball 322′ are different. For example, the respective second conductive ball 322′ has a substantially circular cross-section, and the respective first conductive ball 321′ has an arcuate non-circular cross-section (e.g., oval cross-section, elliptical cross-section, spherical cross-section, etc.). The first conductive balls 321′ and the second conductive balls 322′ may each include two equatorial radii along the x and y-axis and a polar radius along the z-axis. The polar radius of the respective first conductive ball 321′ may be greater than both of the equatorial radii of the respective first conductive ball 321′. The second conductive balls 322′ may have all radii that are substantially the same.

As shown in FIG. 4A, the cross-section of the respective first conductive ball 321′ includes a first axis (e.g., a long-axis or a major axis) along the Z-direction and a second axis (e.g., a short-axis or a minor axis) along the X-direction or the Y-direction, where the diameter BH1 along the major axis is greater than the diameter BD1 along the minor axis. For example, the respective first conductive ball 321′ is an ovoid, ellipsoid, spheroid, or the like. The diameter BD1 of the respective first conductive ball 321′ may be less than the lateral dimension OD1 of the first opening OP1 so that the respective first conductive ball 321′ may pass through the first opening OP1. For example, a ratio of the lateral dimension OD1 to the diameter BD1 is in a range of about 5% and about 10%. The cross-section of the respective second conductive ball 322′ includes a first axis along the Z-direction and a second axis along the X-direction or the Y-direction, where the diameter BH2 along the first axis is substantially equal to the diameter BD2 along the second axis. The diameter (BD2 or BH2) of the respective second conductive ball 322′ may be less than the lateral dimension OD2 of the second opening OP2 so that the respective second conductive ball 322′ may pass through the second opening OP1. For example, a ratio of the lateral dimension OD2 to the diameter BD2 is in a range of about 5% and about 10%.

With continued reference to FIG. 4A, the respective first conductive ball 321′ may include a conductive core 3211, a conductive coating 3212 wrapping around the conductive core 3211, and a conductive shell 3213 wrapping around the conductive coating 3212, where the conductive core 3211, the conductive coating 3212, and the conductive shell 3213 are made of different materials. The conductive core 3211 may include Cu, alloy thereof, or the like. The conductive coating 3212 may include Ag, Co, Bi, Zn, Ni, alloys thereof, combination thereof, etc. The conductive coating 3212 may be a single layer or may be a composite layer including different materials. The conductive shell 3213 may include a solder material which is made of Sn, SnAg, Sn—Pb, SnAgCu, SnAgZn, SnZn, SnBi—In, Sn—In, Sn—Au, SnPb, SnCu, SnZnIn, SnAgSb, etc.

With continued reference to FIG. 4A, the respective second conductive ball 322′ may include a conductive core 3221, a conductive coating 3222 wrapping around the conductive core 3221, and a conductive shell 3223 wrapping around the conductive coating 3222, where the conductive core 3221, the conductive coating 3222, and the conductive shell 3223 are made of different materials. The conductive core 3221 may include Cu, alloy thereof, or the like. In some embodiments, the conductive cores (3211 and 3221) are made of the same/similar metallic material(s). The conductive coating 3222 may include Ni, alloys thereof, combination thereof, etc. The conductive coating 3212 may be a single layer or may be a composite layer including different materials. For example, the material of the conductive coating 3222 of the respective second conductive ball 322′ is different from the material of the conductive coating 3212 of the respective first conductive ball 312′. The conductive shell 3223 may include a solder material which is made of Sn, SnAg, Sn—Pb, SnAgCu, SnAgZn, SnZn, SnBi—In, Sn—In, Sn—Au, SnPb, SnCu, SnZnIn, SnAgSb, etc.

Referring to FIGS. 5A-5B and with reference to FIGS. 4A-4B, after the first conductive balls 321′ and the second conductive balls 322′ land on the contact pads 311B, a reflow process may be performed on the first conductive balls 321′ and the second conductive balls 322′ to respectively form first terminal structures 321 and second terminal structures 322. A physical and electrical connection may be made between the respective terminal structure (e.g., the first terminal structures 321 and the second terminal structures 322) and the corresponding contact pad 311B of the third package component 300. During the reflow process, the conductive shells (3213 and 3223) may be reflowed. In some embodiments, the reflow temperature is in a range from about 150° C. to about 250° C., such as about 200° C. Depending on the materials of the first conductive balls 321′ and the second conductive balls 322′, the reflow temperature and process parameters may vary. The reflow process may change the cross-sectional profiles of the conductive shells (3213 and 3223) due to the reflow temperature being near (or exceeding) the melting temperature of the solder material. In some embodiments, after the reflow process, the temporary carrier 53 is removed from the device package 10 to reveal the first surface 120a of the insulating encapsulation 120 and the second sides 110b of the semiconductor dies 110 by, e.g., de-bonding the temporary adhesive layer DF1 or using any suitable removal techniques.

As shown in the enlarged cross-sectional view (i.e. the dashed box A) in FIG. 5A, the first terminal structure 321 may include the conductive core 3211, the conductive coating 3212 encircling the conductive core 3211, the conductive shell 3213 wrapping around the conductive coating 3212 and connected to the contact pad 311B, and an intermetallic compound (IMC) layer C1 formed at the interface between the conductive coating 3212 and the conductive shell 3213. The contact pad 311B may be physically separated from the conductive coating 3212 by a portion of the conductive shell 3213 (and the IMC layer C1, if any). The portion of the conductive shell 3213 may include a thickness Tc1 which is non-zero. For example, the conductive core 3211 is suspended in the solder layer (e.g., the conductive shell 3213). The conductive core 3211 may have an arcuate non-circular cross-section (e.g., oval cross-section, elliptical cross-section, spherical cross-section, etc.). For example, the conductive core 3211 is an ovoid, ellipsoid, or spheroid. The cross-section of the conductive core 3211 may include a first axis (e.g., a long-axis or a major axis) along the Z-direction and a second axis (e.g., a short-axis or a minor axis) along the X-direction or the Y-direction, where the diameter DC1 along the major axis is greater than the diameter DB1 along the minor axis. A ratio of the diameter DB1 to the diameter DC1 is greater than 0 and less than 1. The conductive coating 3212 may have a thickness Tb which is non-zero. For example, the thickness Tb is substantially equal to 10 nm or greater than 10 nm.

As shown in the enlarged cross-sectional view (i.e. the dashed box B) in FIG. 5A, the second terminal structure 322 may include the conductive core 3221, the conductive coating 3222 encircling the conductive core 3221, the conductive shell 3223 wrapping around the conductive coating 3222 and connected to the contact pad 311B, and an intermetallic compound (IMC) layer C2 formed at the interface between the conductive coating 3222 and the conductive shell 3223. The contact pad 311B may be physically separated from the conductive coating 3222 by a portion of the conductive shell 3223 (and the IMC layer C2, if any). The portion of the conductive shell 3223 may include a thickness Tc2 which is non-zero. For example, the conductive core 3221 is suspended in the solder layer (e.g., the conductive shell 3223). The conductive core 3221 may have a substantially circular cross-section. For example, the conductive core 3211 is a substantially round ball having spherical shape. The cross-section of the conductive core 3211 may include a first axis along the Z-direction and a second axis along the X-direction or the Y-direction, where the diameter DD1 along the first axis is substantially equal to than the diameter DD1 along the second axis. A ratio of the diameter DD1 to the diameter DD1 is substantially equal to 1. The conductive coating 3222 may have a thickness Ts which is non-zero. For example, the thickness Ts is substantially equal to 10 nm or greater than 10 nm.

With continued reference to the dashed boxes A and B in FIG. 5A, the overall size and the volume of the first terminal structure 321 may be greater that the overall size and the volume of the second terminal structure 322. The first terminal structure 321 may be viewed as a large terminal, while the second terminal structure 322 may be viewed as a small terminal. The cross-sectional area of the conductive core 3211 of the first terminal structure 321 may be greater than the cross-sectional area of the conductive core 3221 of the second terminal structure 322. For example, the diameter DC1 of the conductive core 3211 of the first terminal structure 321 is greater than the diameter DD1 of the conductive core 3221 of the second terminal structure 322 along the Z-direction. The diameter DB1 of the conductive core 3211 of the first terminal structure 321 may be greater than or substantially equal to the diameter DD1 of the conductive core 3211 of the second terminal structure 322 along the X or Y-direction. In some embodiments, the ratio of (DC/DB1) is greater than the ratio of (DD1/DD1).

With continued reference to FIG. 5A, during the reflow process, the tin in the conductive shell (e.g., 3213 and 3223) may tend to migrate and react with the conductive coating (e.g., 3212 and 3222) to form the IMC layer (e.g., C1 and C2). The conductive coating (e.g., 3212 and 3222) may be consumed during the IMC formation. For example, the reflow process causes the IMC layer C1 to be formed at the interface between the conductive shell 3213 and the conductive coating 3212 and causes the IMC layer C2 formed at the interface between the conductive shell 3223 and the conductive coating 3222. The IMC layers (C1 and C2) may each be a material formed by a reaction between the material of the conductive shell (e.g., the solder material) and the material conductive coating (e.g., Ag, Co, Zn, Bi, Ni, etc.). The IMC layer C1 in the respective first terminal structure 321 and the IMC layer C2 in the respective second terminal structure 322 may include different compositions.

In some embodiments where the conductive coating 3222 is made of Ni and the conductive shell 3223 is made of solder, the IMC layer C2 in the respective second terminal structure 322 is a tin-nickel alloy such as Ni₃Sn₄ or the like. In some embodiments where the conductive coating 3212 is made of Ag and the conductive shell 3213 is made of solder, the IMC layer C1 in the respective first terminal structure 321 is a tin-silver alloy such as Ag₃Sn or the like. When the conductive coating 3212 is made of Co, the IMC layer C1 may be CoSn₃. When the conductive coating 3212 is made of Zn, the IMC layer C1 may be Zn. When the conductive coating 3212 is made of Bi, the IMC layer C1 may be Bi. The conductive coating (e.g., 3212 and 3222) may be made of any suitable metallic material which can react with the conductive shell (e.g., 3213 and 3223) to form the IMC layer, and such IMC layer may be configured to reduce or inhibit Cu diffusion from the contact pads 311B into the corresponding conductive shell (e.g., 3213 and 3223). If Cu in the contact pads 311B is consumed too fast, an open-circuit fault may occur. By configuring the conductive coating between the conductive shell and the conductive core to form the IMC layer at the interface between the conductive shell and the conductive coating, the Cu diffusion from the contact pads 311B into the conductive shell may be effectively inhibited.

With continued reference to FIG. 5B, the first terminal structures 321 may be arranged within the first region R1, while the second terminal structures 322 may be distributed within the second region R2. For example, the maximum length LA1 of the first region R1 is less than the maximum length LA2 of the second region R2 in the top-down view. A ratio of the maximum length LA1 to the maximum length LA2 may be greater than 0 and less than 1. In some embodiments, the maximum length LA2 of the second region R2 is substantially equal to the length of the second side 300b of the third package component 300. The maximum width WA1 of the first region R1 may be less than the maximum width WA2 of the second region R2 in the top-down view. A ratio of the maximum width WA1 to the maximum width WA2 may be greater than 0 and less than 1. In some embodiments, the maximum width WA2 of the second region R2 is substantially equal to the width of the second side 300b of the third package component 300. It should be noted that the number of the first terminal structures 321 in the first region R1 and the number of the second terminal structures 322 in the second region R2 illustrated in FIG. 5B are merely examples and construe no limitation in the disclosure.

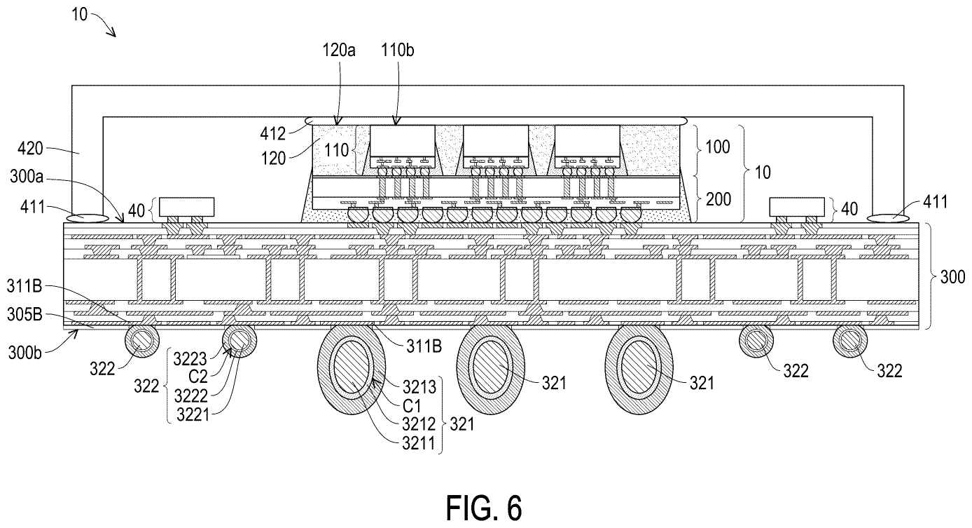

Referring to FIG. 6 and with reference to FIG. 5A, after the reflow process, the structure shown in FIG. 5A may be flipped upside-down, and then a lid 420 may be attached to the third package component 300 and the device package 10 through a first adhesive layer 411 and a second adhesive layer 412, respectively. For example, the first adhesive layer 411 formed on the first side 300a of the third package component 300 includes any suitable adhesive material including a viscous gel or liquid material, such as thermal grease, silver paste, solder, polymeric adhesive, or the like. The material of the first adhesive layer 411 may or may not have a high thermal conductivity. The second adhesive layer 412 formed on the first surface 120a of the insulating encapsulation 120 and the second sides 110b of the semiconductor dies 110 may include any suitable material which has a high thermal conductivity for effectively dissipating the heat generated by the semiconductor dies 110 into the lid 420. In some embodiments, the second adhesive layer 412 is a thermal interface material (TIM) layer which is designed with specific characteristics to meet specific requirements. The second adhesive layer 412 may have higher thermal conductivity in some instances, while in alternative embodiments, the second adhesive layer 412 may have better adhesion.

With continued reference to FIG. 6, after attachment of the lid 420 on the first side 300a of the third package component 300, the third package component 300 and the lid 420 may define a cavity within which the device package 10 is included. The lid 420 may be rigid enough to protect the device package 10 and the third package component 300. In some embodiments, the lid 420 counter-balances the force exerted by the mismatch that is caused by the CTEs between the device package 10 and the third package component 300. It should be noted that the lid 420 may come in a variety of shapes and sizes as feasibly permitted depending on product requirements. The lid 420 may be configured to spread heat generated from the device package 10 to a larger area and/or dissipate the heat from the device package 10. The lid 420 may be a heat dissipating component (e.g., heat sink, heat spreader, or the like) placed over the device package 10 by, e.g., a placement process. The material of the lid 420 may be or may include Cu, Al, Ag, steel, stainless steel, metal alloy, combinations thereof, and/or other suitable material(s) having high thermal conductivities. In some embodiments, the lid 420 is an integrated-formed component. Alternatively, the lid 420 includes more than one piece that may be of the same or different materials, e.g., the lid may include stiffeners adhered to the third package component and an upper plate adhered to the stiffeners.

With continued reference to FIG. 6, a package structure 10 is provided. The package structure 10 may include a device package 10 stacked upon and bonded to the first side 300a of the third package component 300, the first terminal structures 321 and the second terminal structures 322 arranged at the second side 300b of the third package component 300 for further electrical connection, and the lid 420 attached to the first side 300a of the third package component 300 and the device package 10 to dissipate the heat generated from the semiconductor dies 110 of the device package 10. In some embodiments, the device package 10 and the third package component 300 are collectively viewed as a chip-on-wafer-on-substrate structure. It should be noted that the chip-on-wafer-on-substrate structure may be replaced with any suitable type of three-dimensional integrated circuit structure. The package structure 10 may include larger terminals (e.g., the first terminal structures 321) arranged directly below the device package 10 and smaller terminals (e.g., the second terminal structures 322) distributed around the larger terminals.

With continued reference to FIG. 6, for the respective first terminal structure 321, the conductive core 3211 may be wrapped around by the conductive shell 3213 with the conductive coating 3212 interposed therebetween, and the IMC layer C1 may be formed at the interface between the conductive shell 3213 and the conductive coating 3212. Similarly, for the respective second terminal structure 322, the conductive core 3221 may be wrapped around by the conductive shell 3223 with the conductive coating 3222 interposed therebetween, and the IMC layer C2 may be formed at the interface between the conductive shell 3223 and the conductive coating 3222. The local crowding effect may be alleviated by coupling the terminal structure (e.g., the first terminal structure 321 and the second terminal structure 322) to the contact pads 311B, as compared to the solder terminal (e.g., no copper core included therein) coupled to the contact pads 311B, thereby improving the electromigration performance. In some instances where the solder terminal coupled to the contact pads 311B, the current density in the solder terminal can become high at the periphery of the interface between the solder terminal and the contact pad. This may lead to electromigration that can be caused by causing local current crowding. Due to the current crowding effect, the electric stress may be induced at the solder interface and cause a failed circuit. It is appreciated that the resistance of copper is lower than that of the solder material. By providing the copper core (e.g., the conductive cores 3211 and 3221) in the terminal structures (e.g., 321, 322), the electron flow may tend to travel along the middle portion of the respective conductive core (3211, 3221), thereby alleviating the local crowding effect and improving the electromigration performance.

With continued reference to FIG. 6, the respective first terminal structure 321 may include the conductive core 3211 larger than the conductive core 3221 of the respective second terminal structure 322. For example, the conductive core 3211 of the respective first terminal structure 321 has the cross-sectional area greater than the cross-sectional area of the conductive core 3221 of the respective second terminal structure 322. The greater the cross-section area of the conductive core is, the minor the local crowding effect to the terminal structure and the contact pad is. By configuring the first terminal structures 321 including larger conductive cores 3211 in the first region R1 overlapping the device package 10, not only the cold joint issue generated by the warpage may be advantageously minimized or substantially eliminated, but also the electromigration performance of the package structure may be improved.

Still referring to FIG. 6, the conductive coating 3212 of the respective first terminal structure 321 may have a metallic material(s) different from the metallic material(s) of the conductive coating 3222 of the respective second terminal structure 322. The IMC layer C1 in the respective first terminal structure 321 may have a different composition than the IMC layer C2 in the respective second terminal structure 322. By configuring the conductive coating between the conductive shell and the conductive core, the current carrying capability of the IMCs may be improved. The metallic material of the conductive coating 3212 may be selected to reduce or inhibit a reaction between the conductive shell 3213 and the contact pad 311B that can form the IMC. In some embodiments, the conductive coating 3212 is configured to reduce solder source and interrupt the path of solder diffusion. In this manner, a more robust connection between the first terminal structures 321 and the contact pads 311B may be provided in the first region R1 (e.g., the warpage-dominating region), and the performance and the reliability of the package structure 10 may be improved.

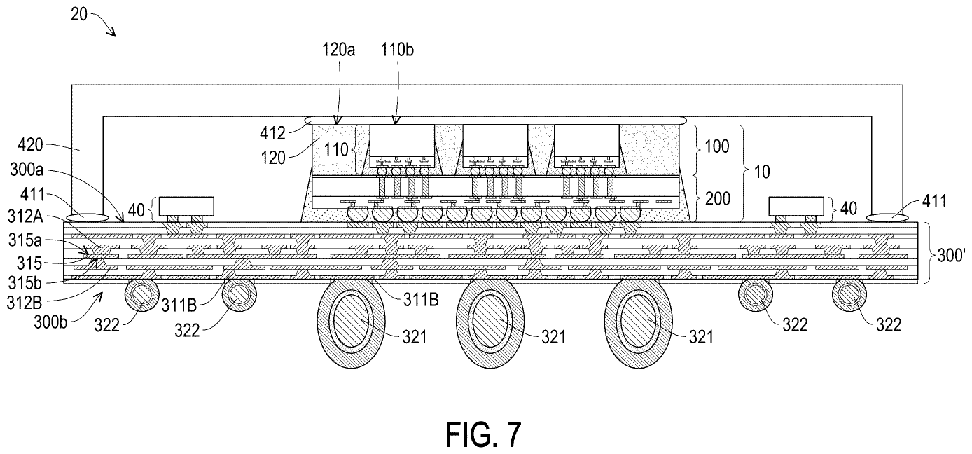

FIG. 7 is a schematic cross-sectional view of another implementation of a package structure, in accordance with some embodiments. The package structure 20 in FIG. 7 may be similar to the package structure 10 described with reference to FIG. 6. Only the differences therebetween will be discussed, the like or the same part will not be repeated again, and the like numeral references indicate the like elements. Referring to FIG. 7 and with reference to FIG. 6, the difference between the package structure 20 and the package structure 10 lies in the third package component. For example, the third package component 300′ of the package structure 20 is a coreless substrate.

With continued reference to FIG. 7, the third package component 300′ includes main conductive pads 315 including a first side 315a and a second side 315b opposite to the first side 315a. The bottommost one of the trace layers 312A may be in physical and electrical contact with the first side 315a of the main conductive pads 315, and bottommost one of the trace layers 312B may be in physical and electrical contact with the second side 315b of the main conductive pads 315. For example, the conductive vias of the bottommost one of the trace layers 312A landing on the main conductive pads 315 are tapered in a direction from the first side 315a toward the second side 315b, while the conductive vias of the bottommost one of the trace layers 312B landing on the main conductive pads 315 are tapered in an opposing direction. For the third package component 300′, the core layer and the through-vias penetrating through the core layer (shown in FIG. 6) are omitted.

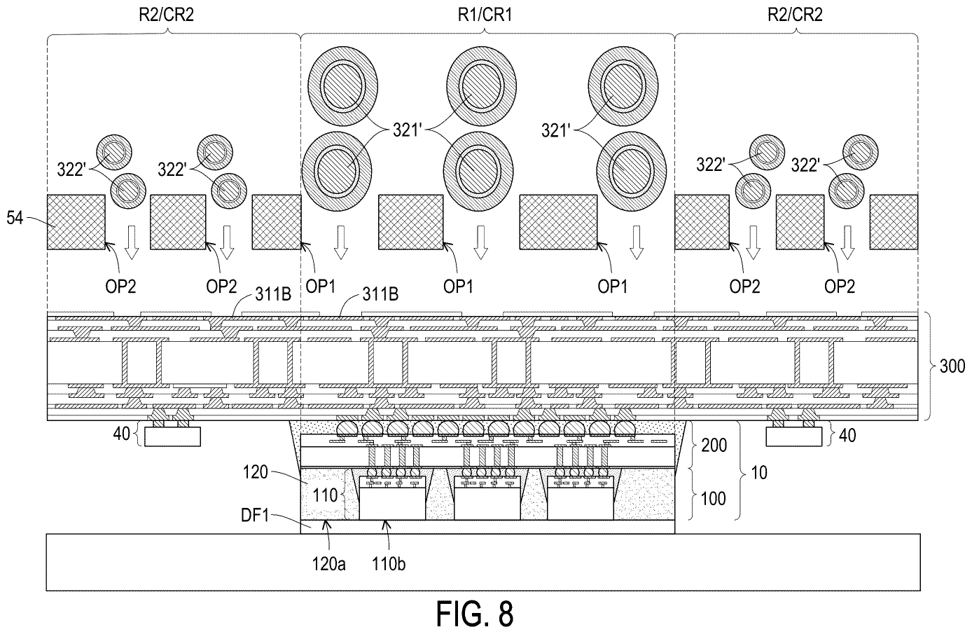

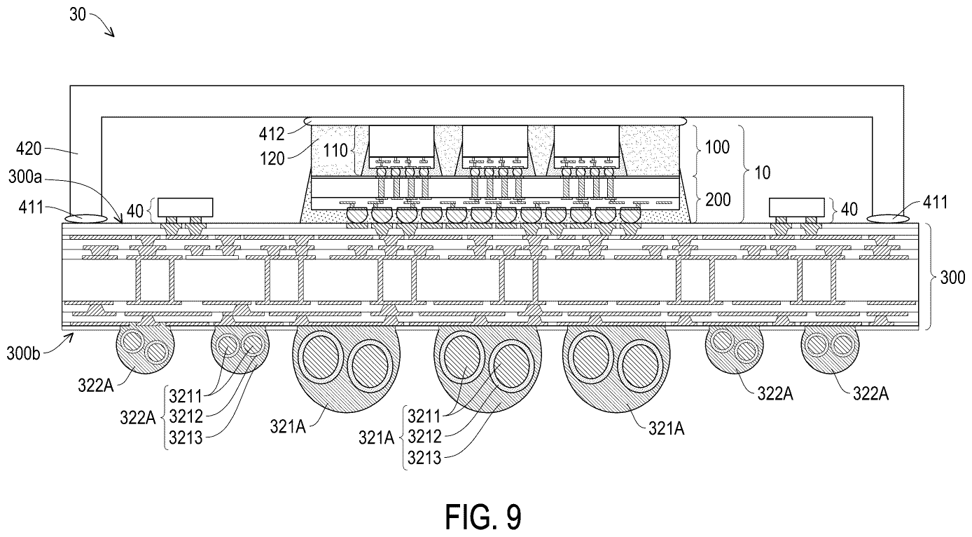

FIGS. 8-9 are schematic cross-sectional views of various stages of manufacturing a package structure, in accordance with some embodiments. The manufacturing process of the package structure package structure 30 in FIGS. 8-9 may be similar to that of the package structure 10 described with reference to FIGS. 1-6. Only the differences therebetween will be discussed, the like or the same part will not be repeated again, and the like numeral references indicate the like elements.

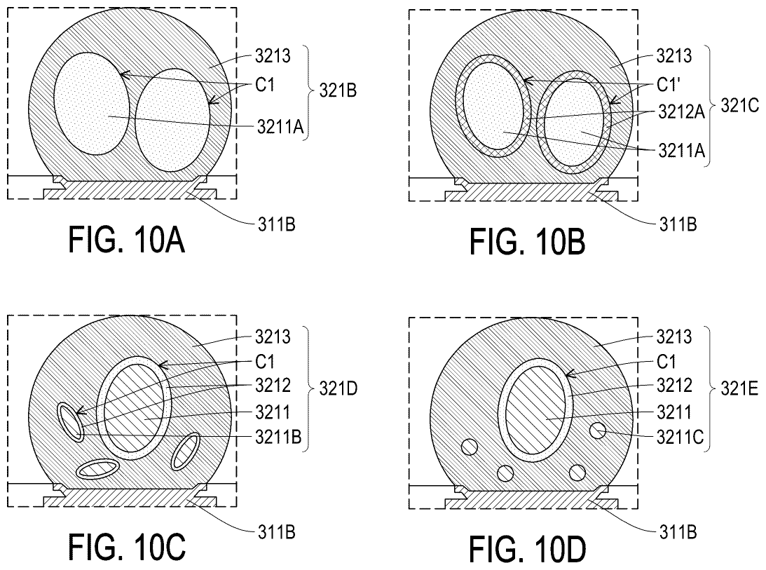

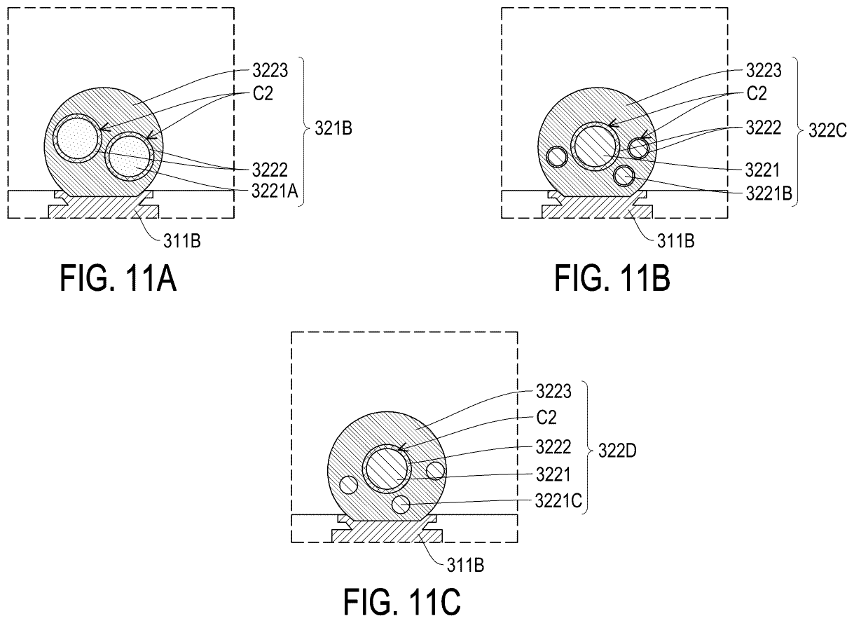

Referring to FIG. 8 and with reference to FIG. 4A, the structure shown in FIG. 8 is similar to the structure shown in FIG. 4A, except that more than one conductive ball (e.g., 321′, 322′) pass through the corresponding openings (e.g., OP1, OP2) of the mask structure 54. For example, two (or more than two) of the first conductive balls 321′ pass through the respective first opening OP1 to land on a same contact pad 311B. Similarly, two (or more than two) of the second conductive balls 322′ may pass through the respective second opening OP2 to land on a same contact pad 311B. In some embodiments, these two (or more than two) of the first conductive balls 321′ are substantially identical. These two (or more than two) of the second conductive balls 321′ may be substantially identical. In alternative embodiments, conductive balls having different sizes/structures drop into a same opening (e.g., OP1, OP2) to land on a same contact pad 311B as will be described later in accompanying with FIGS. 10C-10D and FIGS. 11B-11C.

Referring to FIG. 9 and with reference to FIG. 8 and FIG. 6, after the ball placement process, a reflow process may be performed as described in FIG. 5A to respectively form first terminal structures 321A and second terminal structures 322A. After forming the first terminal structures 321A and the second terminal structures 322A, the temporary carrier 53 may be removed from the device package 10 to reveal the first surface 120a of the insulating encapsulation 120 and the second sides 110b of the semiconductor dies 110 by, e.g., de-bonding the temporary adhesive layer DF1 or using any suitable removal techniques. Next, the lid 420 may be attached to the third package component 300 and the device package 10 through the first adhesive layer 411 and the second adhesive layer 412, respectively, as described in FIG. 6.

With continued reference to FIG. 9 and FIG. 6, a package structure 30 may be provided. The package structure 30 is similar to the package structure 10 descried in FIG. 6, except that each of the terminal structures (e.g., 321A, 322A) includes a plurality of conductive cores (e.g., 3211, 3221) suspended in the solder layer (e.g., the corresponding conductive shell), where each of the conductive cores (e.g., 3211, 3221) is coated with the corresponding conductive coating (e.g., 3212, 3222). For the respective first terminal structure 321A, two conductive cores 3211 may be wrapped by the conductive shell 3213, these two conductive cores 3211 are separated from each other, and each conductive core 3211 is coated with the conductive coating 3212. Similarly, two of the conductive cores 3221 may be wrapped by the conductive shell 3223, these two conductive cores 3221 are separated from each other, and each conductive core 3221 is coated with the conductive coating 3222. The conductive cores (e.g., 3211, 3221) wrapped by a same conductive shell (e.g., 3213, 3223) may be substantially identical (e.g., having a same size/volume/weight, etc.) Alternatively, conductive cores having different sizes may be wrapped by a same conductive shell as will be described later in accompanying with FIGS. 10C-10D and FIGS. 11B-11C.

FIGS. 10A-10D are schematic enlarged cross-sectional view of a first terminal structure, in accordance with some embodiments. The first terminal structures in FIGS. 10A-10D may be similar to the first terminal structures 321 and 321A described with reference to FIG. 5A and FIG. 9. One or more than one of the first terminal structures of the package structure shown FIG. 5A and/or FIG. 9 may be replaced with the first terminal structure(s) described in FIGS. 10A-10D. Only the differences therebetween will be discussed, the like or the same part will not be repeated again, and the like numeral references indicate the like elements.

Referring to FIG. 10A and with reference to FIG. 9, the first terminal structure 321B is similar to the first terminal structure 321A, except that these two conductive cores 3211A of the first terminal structure 321B are made of a different metallic material than the conductive core 3211. In some embodiments, the conductive cores 3211A of the first terminal structure 321B are made of Ag, alloy thereof, or the like. In some embodiments, the conductive cores 3211A have the same size/volume. Alternatively, the conductive cores 3211A are of different sizes and/or different materials. The conductive coating may be omitted in the first terminal structure 321B. For example, the conductive cores 3211A are wrapped by the conductive shell 3213 of the first terminal structure 321B without any conductive coating interposed therebetween. In some embodiments, the first terminal structure 321B includes the IMC layer C1 formed at the interface between the conductive cores 3211A and the conductive shell 3213.

Referring to FIG. 10B and with reference to FIG. 10A, the first terminal structure 321C is similar to the first terminal structure 321B, except that each of the conductive cores 3211A is coated with a conductive coating 3212A. The conductive coating 3212A and the corresponding conductive core 3211A may be made of different metallic materials. For example, the conductive core 3211A is made of Ag, alloy thereof, or the like, while the conductive coating 3212A is made of Co, Zn, Bi, Ni, etc. The first terminal structure 321C may include the IMC layer C1′ formed at the interface between the conductive coating 3212A and the conductive shell 3213. The IMC layer C1′ may include CoSn₃, Zn, Bi, Ni₃Sn₄, etc. depending on the material(s) of the conductive coating 3212A.

Referring to FIG. 10C and with reference to FIG. 9, the first terminal structure 321D is similar to the first terminal structure 321A, except that the first terminal structure 321D includes at least one primary conductive core 3211 and more than one secondary conductive cores 3211B. The respective secondary conductive core 3211B may be similar to the primary conductive core 3211, except that the secondary conductive core 3211B has a size smaller than the primary conductive core 3211. Each of the primary conductive core 3211 and the secondary conductive cores 3211B may be coated with the conductive coating 3212. In some embodiments, the primary conductive core 3211 and the secondary conductive cores 3211B are made of the same/similar metallic material(s) such as Cu, alloy thereof, etc. In alternative embodiments, the primary conductive core 3211 and the secondary conductive cores 3211B are made of Ag, alloy thereof, etc. In some other embodiments, the primary conductive core 3211 and the secondary conductive cores 3211B are made of different metallic materials.

Referring to FIG. 10D and with reference to FIG. 10C, the first terminal structure 321E is similar to the first terminal structure 321D, except that the secondary conductive cores 3211B are replaced with metallic beads 3211C. In some embodiments, the metallic beads 3211C are not coated with any conductive coating. For example, the primary conductive core 3211 has a size greater than that of the respective metallic bead 3211C. In some embodiments, the primary conductive core 3211 and the metallic beads 3211C are made of the same/similar metallic material(s) such as Cu, alloy thereof, etc. In alternative embodiments, the primary conductive core 3211 and the metallic beads 3211C are made of Ag, alloy thereof, etc. In some other embodiments, the primary conductive core 3211 and the metallic beads 3211C are made of different metallic materials.

With continued reference to FIGS. 9 and 10A-10D, for the respective first terminal structure (e.g., 321A, 321B, 321C, 321D, and 321E), a ratio of a total volume of the conductive cores (including primary and secondary conductive cores, or including primary conductive cores and the metallic beads) to a total volume of the first terminal structure may be in a range of about 45% and about 95%. It is noted that the values are merely examples and may be adjusted in accordance with various embodiments.

FIGS. 11A-11C are schematic enlarged cross-sectional view of a second terminal structure, in accordance with some embodiments. The second terminal structures in FIGS. 11A-11C may be similar to the second terminal structures 322 and 322A described with reference to FIG. 5A and FIG. 9. One or more than one of the second terminal structures of the package structure shown FIG. 5A and/or FIG. 9 may be replaced with the second terminal structure(s) described in FIGS. 11A-11C. Only the differences therebetween will be discussed, the like or the same part will not be repeated again, and the like numeral references indicate the like elements.

Referring to FIG. 11A and with reference to FIG. 9, the second terminal structure 322B is similar to the second terminal structure 322A, except that these two conductive cores 3221A of the second terminal structure 322B are made of a different metallic material than the conductive core 3221. In some embodiments, the conductive cores 3221A of the second terminal structure 322B are made of Ag, alloy thereof, or the like. In some embodiments, the conductive cores 3221A includes a substantially same size/volume. Alternatively, the conductive cores 3221A are of different sizes and/or different materials. For example, the conductive cores 3221A are wrapped by the conductive shell 3213 of the first terminal structure 321B with the conductive coating 3222 interposed therebetween. The conductive coating 3222 may be made of Ni, Co, alloy thereof, etc. The second terminal structure 322B may include the IMC layer C2 formed at the interface between the conductive coating 3222 and the conductive shell 3223, and the composition of the IMC layer C2 may depend on the metallic material of the corresponding conductive coating 3222.

Referring to FIG. 11B and with reference to FIG. 9, the second terminal structure 321C is similar to the first terminal structure 322A, except that the first terminal structure 322C includes at least one primary conductive core 3221 and more than one secondary conductive cores 3221B. The respective secondary conductive core 3221B may be similar to the primary conductive core 3221, except that the secondary conductive core 3221B has a size smaller than the primary conductive core 3221. Each of the primary conductive core 3221 and the secondary conductive cores 3221B may be coated with the conductive coating 3222. In some embodiments, the primary conductive core 3221 and the secondary conductive cores 3221B are made of the same/similar metallic material(s) such as Cu, alloy thereof, etc. In alternative embodiments, the primary conductive core 3221 and the secondary conductive cores 3221B are made of Ag, alloy thereof, etc. In some other embodiments, the primary conductive core 3221 and the secondary conductive cores 3221B are made of different metallic materials.

Referring to FIG. 11C and with reference to FIG. 11B, the second terminal structure 322D is similar to the first terminal structure 322C, except that the secondary conductive cores 3221B are replaced with metallic beads 3221C. In some embodiments, the metallic beads 3221C are not coated with any conductive coating. For example, the primary conductive core 3221 has a size greater than that of the respective metallic bead 3221C. In some embodiments, the primary conductive core 3221 and the metallic beads 3221C are made of the same/similar metallic material(s) such as Cu, alloy thereof, etc. In alternative embodiments, the primary conductive core 3221 and the metallic beads 3221C are made of Ag, alloy thereof, etc. In some other embodiments, the primary conductive core 3221 and the metallic beads 3221C are made of different metallic materials.

With continued reference to FIGS. 9 and 11A-11C, for the respective second terminal structure (e.g., 322A, 322B, 322C, and 322D), a ratio of a total volume of the conductive cores (including primary and secondary conductive cores, or including primary conductive cores and the metallic beads) to a total volume of the second terminal structure may be in a range of about 45% and about 95%. It is noted that the values are merely examples and may be adjusted in accordance with various embodiments.

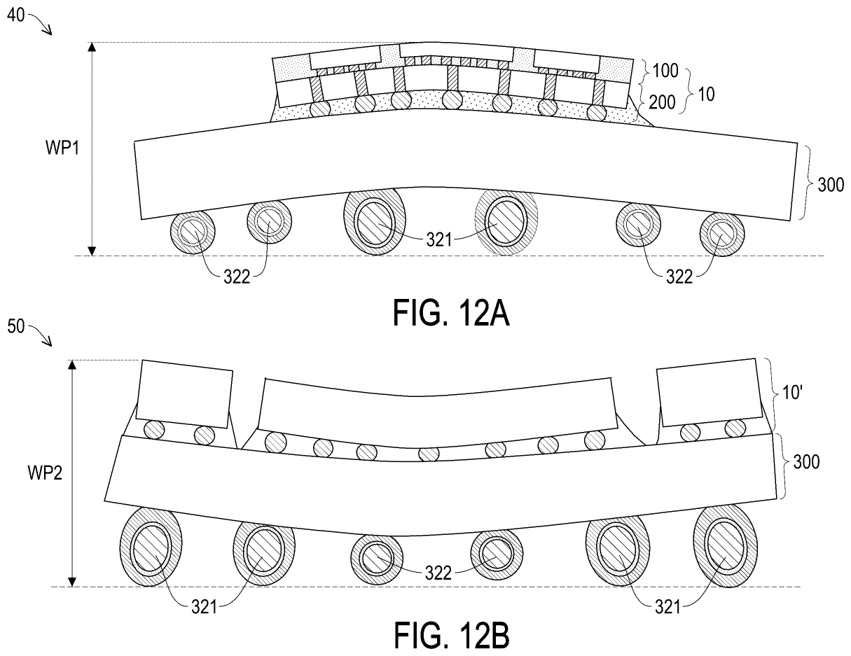

FIGS. 12A and 12B are schematic cross-sectional view of other implementations of a package structure, in accordance with some embodiments. It should be noted that the package structures illustrated in FIGS. 12A-12B are simplified, and the details of the package structures may refer to the package structures (e.g., 10, 20, 30) described in the preceding paragraphs. The following discussions associated with FIGS. 12A-12B focus on the warpage of the package structure and the distribution of the first and second terminal structures.

Referring to FIG. 12A, the package structure 40 shown in FIG. 12A may be similar to the package structure 10 described in FIG. 6, except that the lid and the associated adhesive are not shown, and the package structure 40 is illustrated to have a convex warpage (e.g., crying cross-sectional profile). In some embodiments, the package structure 40 includes the first terminal structures 321 distributed in the central region of the package structure 40 and the second terminals structures 322 distributed in the peripheral region of the package structure 40. The distribution region of the first terminal structures 321 on the third package component 300 may overlap the orthogonal projection of the device package 10 on the third package component 300. The distribution region of the second terminals structures 322 may surround the distribution region of the first terminal structures 321. The package structure 40 heated under the elevated temperature may be warped with a certain warpage level. For example, the vertical distance WP1 between the topmost point of the package structure 40 and the bottommost point of the package structure 40 is in a range of about 50 microns and about 300 microns. Even though the package structure 40 is warped downwardly, by configuring different sizes of the terminal structures (e.g., 321 and 322) in the predetermined regions, the coplanarity of the package structure 40 may be reduced, and the flatness of the package structure 40 may be improved.

Referring to FIG. 12B and with reference to FIG. 12A, the package structure 50 may include a plurality of device packages 10′ bonded to the third package component 300. The respective device package 10′ may be similar to the device package 10 described in the previous embodiments. In some embodiments, the package structure 50 includes the first terminal structures 321 distributed in the peripheral region of the package structure 50 and the second terminals structures 322 distributed in the central region of the package structure 50 and surrounded by the first terminal structures 321. The package structure 50 heated under the elevated temperature may be warped and present a concave warpage (e.g., smiling cross-sectional profile). For example, the vertical distance WP2 between the topmost point of the package structure 50 and the bottommost point of the package structure 50 is in a range of about 50 microns and about 300 microns. Even though the package structure 50 is warped upwardly, by configuring different sizes of the terminal structures (e.g., 321 and 322) in different regions, the coplanarity of the package structure 50 may be reduced, and the flatness of the package structure 50 may be improved.

In accordance with some embodiments, a package structure includes a package substrate, first and second terminal structures disposed on a first side of the package structure. Each of the first terminal structures includes a first conductive core, a first conductive coating wrapping around the first conductive core, and a first conductive shell wrapping around the first conductive coating. Each of the second terminal structures includes a second conductive core, a second conductive coating wrapping around the second conductive core, and a second conductive shell wrapping around the second conductive coating. The second conductive coating includes a material different from a material of the first conductive coating.

In accordance with some embodiments, a package structure includes a package substrate including a first region and a second region, a device package disposed on a side of the package substrate and within the first region, first terminal structures disposed on an opposing side of the package structure and within the first region, and second terminal structures disposed on the opposing side of the package structure and within the second region. Each of the first terminal structures includes a first solder layer and a first conductive core suspended in the first solder layer. Each of the second terminal structures includes a second solder layer and a second conductive core suspended in the second solder layer, where a cross-sectional area of the first conductive core is greater than that of the second conductive core.

In accordance with some embodiments, a manufacturing method of a package structure includes: coupling a device package to a first side of a package substrate; placing first conductive balls on a second side of the package substrate, where a distribution region of the first conductive balls on the package substrate overlaps an orthogonal projection of the device package on the package substrate; placing second conductive balls on the second side of the package substrate outside the distribution region of the first conductive balls; and reflowing the first and second conductive balls to respectively form first terminal structures and second terminal structures. Each of the first terminal structures includes a first conductive core suspended in a first solder layer, each of the second terminal structures includes a second conductive core suspended in a second solder layer, and a cross-sectional area of the first conductive core is greater than that of the second conductive core.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a first terminal structure disposed on a first side of the package structure, the first terminal structure comprising:
a first conductive core;
a first conductive coating wrapping around the first conductive core;
a first conductive shell wrapping around the first conductive coating; and
a second terminal structure disposed on the first side of the package structure, the second terminal structure comprising:
a second conductive core;
a second conductive coating wrapping around the second conductive core and comprising a material different from a material of the first conductive coating; and
a second conductive shell wrapping around the second conductive coating.

2. The package structure of claim 1, wherein a cross-sectional area of the first conductive core is different than a cross-sectional area of the second conductive core.

3. The package structure of claim 1, wherein a volume of the first terminal structure is different than that of the second terminal structure.

4. The package structure of claim 1, wherein a first dimension of the first conductive core measured along a major axis of the first conductive core is different than a second dimension of the second conductive core measured along a major axis of the second conductive core.

5. The package structure of claim 1, wherein a first ratio of a first dimension of the first conductive core measured along a major axis of the first conductive core to a second dimension of the first conductive core measured along a minor axis of the first conductive core is greater than a second ratio of a third dimension of the second conductive core measured along a major axis of the second conductive core to a fourth dimension of the second conductive core measured along a minor axis of the second conductive core.

6. The package structure of claim 1, wherein:
the first terminal structure further comprises a first intermetallic compound layer between the first conductive shell and the first conductive coating,
the second terminal structure further comprises a second intermetallic compound layer between the second conductive shell and the second conductive coating, and
the first intermetallic compound layer comprises a different composition than the second intermetallic compound layer.

7. The package structure of claim 1, further comprising:
a device package disposed on a second side of the package substrate opposite to the first side, wherein a distribution region of the first terminal structure on the package substrate overlaps an orthogonal projection of the device package on the package substrate.

8. The package structure of claim 1, wherein the first conductive shell and the second conductive shell comprise a solder material and are joined to corresponding contact pads of the package substrate.

9. The package structure of claim 1, wherein the first conductive core comprises a material different from the material of the first conductive coating, and the second conductive core comprises a material different from the material of the second conductive core.

10. The package structure of claim 1, wherein the first conductive core or the second conductive core comprises a plurality of conductive balls physically separated from one another.

11. The package structure of claim 10, wherein the conductive balls comprise a first conductive ball and a second conductive ball smaller than the first conductive ball.

12. A package structure, comprising:
a package substrate comprising a first region and a second region;
a device package disposed on a side of the package substrate and within the first region;
a first terminal structure disposed on an opposing side of the package structure and within the first region, the first terminal structure comprising a first solder layer and a first conductive core suspended in the first solder layer; and
a second terminal structure disposed on the opposing side of the package structure and within the second region, the second terminal structure comprising a second solder layer and a second conductive core suspended in the second solder layer, wherein a cross-sectional area of the first conductive core is different than that of the second conductive core.

13. The package structure of claim 12, wherein the first conductive core comprises an oval cross-sectional shape and the second conductive core comprises a substantially circular cross-sectional shape.

14. The package structure of claim 12, wherein the first terminal structure further comprises a first conductive coating on the first conductive core and a first intermetallic compound layer between the first conductive coating and the first solder layer.

15. The package structure of claim 14, wherein the second terminal structure further comprises a second conductive coating on the second conductive core, and a material of the second conductive coating is different from that of the first conductive coating.

16. The package structure of claim 12, wherein the first terminal structure land on contact pads of the package substrate, and the first conductive core is separated from a corresponding one of the contact pads by the first solder layer.

17. A manufacturing method of a package structure, comprising:
coupling a device package to a first side of a package substrate;
placing a first conductive ball on a second side of the package substrate, wherein a distribution region of the first conductive ball on the package substrate overlaps an orthogonal projection of the device package on the package substrate;
placing a second conductive ball on the second side of the package substrate outside the distribution region of the first conductive ball; and
reflowing the first and second conductive balls to respectively form a first terminal structure and a second terminal structure, wherein the first terminal structure comprises a first conductive core suspended in a first solder layer, the second terminal structure comprises a second conductive core suspended in a second solder layer, and a cross-sectional area of the first conductive core is greater than that of the second conductive core.

18. The manufacturing method of claim 17, wherein placing the first and second conductive balls comprises:
placing a mask structure over the second side of the package substrate, wherein the mask structure comprises a first opening and a second opening, the first conductive ball passes through the first opening to land on the package substrate, and the second conductive ball passes through the second opening to land on the package substrate.

19. The manufacturing method of claim 17, wherein the first conductive ball further comprises a first conductive coating wrapping around the first conductive core, and the manufacturing method further comprises:
forming a first intermetallic compound layer between the first conductive coating and the first solder layer.

20. The manufacturing method of claim 19, wherein the second conductive ball further comprises a second conductive coating wrapping around the second conductive core and comprising a different material than the first conductive coating, and the manufacturing method further comprises:
forming a second intermetallic compound layer between the second conductive coating and the second solder layer, wherein the second intermetallic compound layer comprises a different composition than the first intermetallic compound layer.
